(19) United States
(12) Patent Application Publication
(10) Pub. No.: US 2025/0351590 A1
(43) Pub. Date: Nov. 13, 2025

(54) SEMICONDUCTOR-BASED RADIATION DETECTORS

(71) Applicant: University of South Carolina, Columbia, SC (US)

(72) Inventor: Krishna C. Mandal, Columbia, SC (US)

(73) Assignee: University of South Carolina, Columbia, SC (US)

(21) Appl. No.: 19/034,140

(22) Filed: Jan. 22, 2025

Related U.S. Application Data
(60) Provisional application No. 63/645,575, filed on May 10, 2024.

(51) Int. Cl. H10F 30/227; G01T 1/24; H10F 30/222; H10F 71/00; H10F 77/1226

(52) U.S. Cl. CPC H10F 30/2275; G01T 1/24; H10F 30/222; H10F 71/1215; H10F 77/1226

(57) ABSTRACT

A radiation detection device includes at least one heterojunction Schottky barrier diode (HSBD). The at least one HSBD includes at least one boron-doped diamond layer located on top of at least one epitaxial layer, the epitaxial layer located on top of at least one buffer layer, and the buffer layer located on top of a bulk substrate layer. At least one contact layer is located on a side of the bulk substrate layer opposite the epitaxial layer.

### CROSS-REFERENCE TO RELATED APPLICATIONS

This application claims priority to U.S. Provisional Application No. 63/645,575 filed on May 10, 2024, the contents of which are incorporated herein by reference in their entirety.

### STATEMENT REGARDING FEDERALLY SPONSORED RESEARCH OR DEVELOPMENT

This invention was made with United States government support under 10011935, 10013007, and 10013350, awarded by the National Aeronautics and Space Administration. The United States government has certain rights in this invention.

### BACKGROUND OF THE INVENTION

The present invention is directed to the field of semiconductor technology, more specifically, to wide bandgap semiconductor based-self-biased radiation detectors.

Silicon carbide (SiC) in its 4H polytype form (4H-SiC) has emerged as a forefront material for electrical quantum metrology as several point defects in 4H-SiC has been identified as solid-state spin defects for storing and manipulating quantum information with extended coherence times.

4H-SiC is a notable semiconductor with a wide bandgap of 3.27 eV at 300 K, offering exceptional thermal conductivity, chemical inertness, physical strength, and radiation hardness and is increasingly recognized as pivotal in semiconductor device technology for harsh environments. Recent advances in epitaxial growth techniques have produced electronic grade epilayers up to 250 μm thick, characterized by excellent charge transport properties and minimal native defects—crucial for optoelectronic device performance.

4H-SiC devices stand out in crystalline quality and compatibility with traditional silicon fabrication methods compared to other wide bandgap semiconductors like aluminum gallium nitride, diamond, and gallium oxide. These properties make epitaxial 4H-SiC the preferred choice for devices and sensors in extreme environments, from nuclear core reactors and space missions to high-energy physics experiments. However, a significant challenge for 4H-SiC devices in harsh conditions is the susceptibility of metal contacts to degradation in corrosive or radiation environments.

In quantum metrology, conventional optical-only readout of spin states accesses only specific charge states (bright states). However, charge state conversion makes the ‘dark states’ readable through electric field application. Electrical charge state identification and control have been demonstrated in nickel/4H-SiC Schottky barrier diodes. Nevertheless, metal contacts like Ni absorb excitation wavelengths, especially in the ultraviolet (UV) region, reducing overall efficiency. Moreover, in radiation detection applications, metal contacts degrade in extreme conditions, limiting detection capabilities in harsh environments like space or in-core (reactor) scenarios.

There is an unmet need in the art for a metal-free 4H-SiC heterojunction Schottky barrier device (HSBD) compatible with harsh environments.

### BRIEF SUMMARY OF THE INVENTION

The present application describes a radiation detection device. The device includes at least one heterojunction Schottky barrier diode (HSBD). The at least one HSBD includes at least one boron-doped diamond (BDD) layer located on top of at least one epitaxial layer, where the at least one epitaxial layer located on top of at least one buffer layer. The at least one buffer layer is located on top of a bulk substrate layer. At least one contact layer is located on a side of the bulk substrate layer opposite the at least one epitaxial layer.

In at least one embodiment of the device, the at least one BDD layer is nanocrystalline p+ boron-doped diamond.

In at least one embodiment of the device, the at least one epitaxial layer is n-type silicon carbide (SIC).

In at least one embodiment of the device, the at least one epitaxial layer is a polytype of SiC selected from 6H-, 4H-, or 3C-polytypes of SiC.

In at least one embodiment of the device, the at least one buffer layer is a polytype of SiC selected from 6H-, 4H-, or 3C-polytypes of SiC.

In at least one embodiment of the device, the bulk substrate layer is n-type silicon carbide (SiC).

In at least one embodiment of the device, the bulk substrate layer is SiC with a 4° off-cut towards the (112°) direction.

In at least one embodiment of the device, the bulk substrate layer is a polytype of SiC selected from 6H-, 4H-, or 3C-polytypes of SiC.

In at least one embodiment of the device, the at least one contact layer is located on a central sample region.

In at least one embodiment of the device, the at least one contact layer is a metal selected from the group consisting of: nickel, molybdenum, and palladium.

In at least one embodiment of the device, at least one curb layer is located on an edge of the HSBD surrounding a central sample region.

In at least one embodiment of the device, the curb layer is selected from the group consisting of silicon dioxide, silicon nitride, zinc oxide, and aluminum nitride.

The present application also includes a method of manufacturing a radiation detection device. The method includes growing at least one epitaxial layer on a substrate layer, cleaning and treating the epitaxial layer to remove a native SiO2 layer, shielding a central sample region from SiO2 deposition, depositing at least one thin curb layer on the edges of the substrate layer to prevent excess growth of at least one BDD layer, growing the at least one BDD layer on at least one epitaxial layer, and depositing at least one contact layer on a side of the substrate layer opposite the at least one BDD layer.

In at least one embodiment of the method, the method includes removing the at least one curb layer.

In at least one embodiment of the method, the at least one curb layer is removed using acid etching.

In at least one embodiment of the method, the at least one epitaxial layer is grown using HWCVD.

In at least one embodiment of the method, the at least one epitaxial layer is cleaned with an RCA clean protocol.

In at least one embodiment of the method, the at least one BDD layer is grown using PECVD.

In at least one embodiment of the method, the at least one contact layer is deposited using physical vapor deposition.

In at least one embodiment of the method, the at least one contact layer is deposited using sputter coating.

### BRIEF DESCRIPTION OF THE SEVERAL VIEWS OF THE DRAWING

FIG. 1a illustrates a perspective view of a radiation detection device.

FIG. 1b illustrates a top view of the radiation detection device during fabrication.

FIG. 1c illustrates a graph of the variation of dark current as a function of forward (positive) and reverse (negative) bias in the radiation detection device.

FIG. 2a illustrates a graph of the variation of dark and photo current as a function of reverse and forward bias measured at room-temperature when the radiation detection device is illuminated with a 365 nm UV radiation.

FIG. 2b illustrates a graph of the variation of output power and absolute current in the radiation detection device as a function of forward bias.

FIG. 2c illustrates a schematic of an alpha spectrometer system used to characterize a nuclear radiation response of the radiation detection device.

FIG. 2d illustrates a pulse height spectrum obtained in the self-biased mode with the radiation detection device illuminated with a ²⁴¹Am alpha particle source.

FIG. 3 illustrates a flowchart of a method of production of the radiation detection device.

### DETAILED DESCRIPTION OF THE INVENTION

In the present description, certain terms have been used for brevity, clearness and understanding. No unnecessary limitations are to be applied therefrom beyond the requirement of the prior art because such terms are used for descriptive purposes only and are intended to be broadly construed. The different systems and methods described herein may be used alone or in combination with other systems and methods. Dimensions and materials identified in the drawings and applications are by way of example only and are not intended to limit the scope of the claimed invention. Any other dimensions and materials not consistent with the purpose of the present application can also be used. Various equivalents, alternatives and modifications are possible within the scope of the appended claims. Each limitation in the appended claims is intended to invoke interpretation under 35 U.S.C. § 112, sixth paragraph, only if the terms “means for” or “step for” are explicitly recited in the respective limitation.

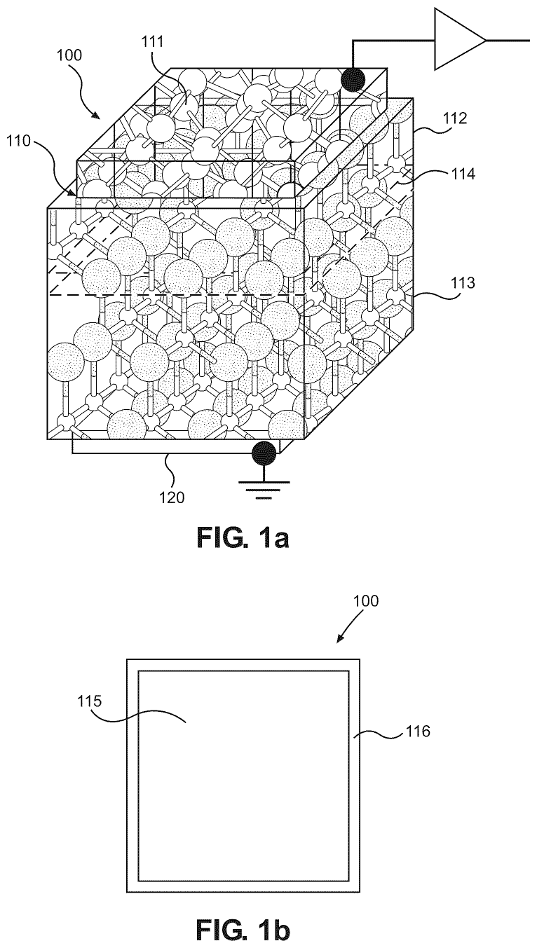

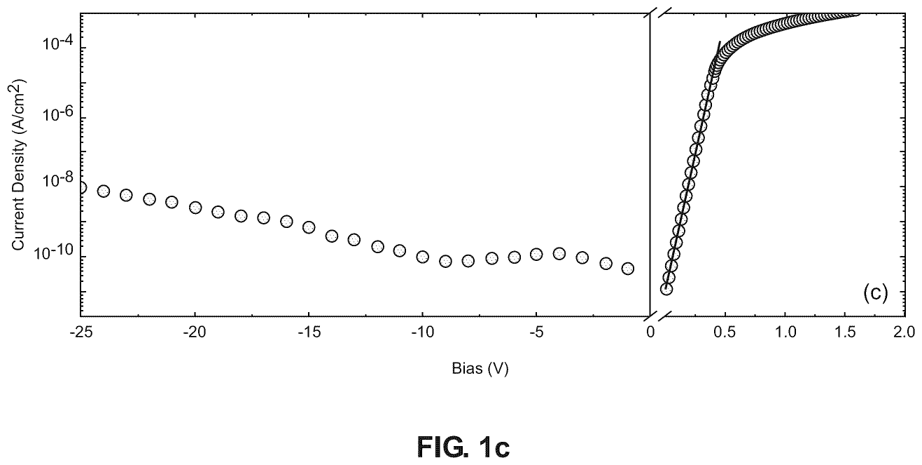

The invention presents an advancement in radiation detection technology such as, but not limited to, ultraviolet (UV) detection. As shown in FIG. 1a, this radiation detection device 100 uses at least one novel (p+)diamond/(n)4H-SiC heterojunction Schottky barrier diode (HSBD) 110. The detection devices 100 have striking utility in harsh environment radiation detection applications where detectors with metal electrodes become unreliable over prolonged use. The device 100 also does not require any input power.

The HSBD 110 integrates at least one boron-doped diamond (BDD) layer 111 with at least one epitaxial layer 112. The BDD layer 111 is a thin, transparent nanocrystalline p+ boron-doped diamond (BDD) layer. The BDD layer 111 is deposited on the epitaxial layers 112 through a vapor deposition process such as, but not limited to, chemical vapor deposition (CVD), plasma enhanced chemical vapor deposition (PECVD), hot filament chemical vapor deposition (HFCVD), or hot-wall chemical vapor deposition (HWCVD). The epitaxial layers 112 are high-quality, low-defect n-type 4H-polytype of silicon carbide (4H-SiC). 4H-SiC epitaxial layers 112 yield exceptional self-biased (zero bias) detection performance. Certain other embodiments may use 6H- or 3C-polytypes of silicon carbide (6H-SiC or 3C-SiC) for the epitaxial layers 112.

The epitaxial layers 112 are separated from a bulk substrate layer 113 by at least one buffer layer 114. The substrate layer 113 is a highly conducting n-type 4H-SiC substrate. Certain other embodiments may use 6H- or 3C-polytypes of silicon carbide (6H-SiC or 3C-SiC) for the substrate layer 113. The buffer layer 114 is a 4H-SiC layer. Certain other embodiments may use 6H- or 3C-polytypes of silicon carbide (6H-SiC or 3C-SiC) for the buffer layer 114.

At least one contact layer 120 is deposited on the side of the substrate layer 113 opposite the BDD layer 111. The contact layers 120 may be metal, such as, but not limited to, nickel, molybdenum, and palladium. The contact layers 120 may cover all or part of a central sample region 115. The contact layers 120 may be deposited using a physical vapor deposition (PVD) method of thin film deposition such as, but not limited to, sputter coating.

In certain embodiments, as shown in FIG. 1b, at least one curb layer 116 may be intentionally deposited on the edges of the substrate layer 113 to prevent excess growth of the BDD layer 111. In certain embodiments where the curb layer 116 remains, the curb layer 116 also provides for a directionality of exposure-with only one exposed plane in the device 100, radiation only contacts a single surface. In one embodiment, the curb layer 116 is a layer of silicon dioxide (SiO₂). Other embodiments may use silicon nitride (Si₃N₄), zinc oxide (ZnO), or aluminum nitride (AlN) for the curb layer 116. During deposition, a mask may shield the central sample region 115 and prevent the curb layer 116 from deposition away from the edge.

In the embodiment shown in FIG. 1a, the nanocrystalline BDD layer 111 has been grown using a PECVD on a 150 μm thick, 8 mm×8 mm epitaxial layer 112. The epitaxial layers 112 were grown using hot-wall CVD on a highly conducting n-type 4H-SiC substrate layer 113, 4° off-cut towards the (112°) direction. Epitaxial layers 112 were cleaned with an RCA clean protocol and treated with 50% diluted hydrofluoric (HF) acid to remove the native SiO2 layer.

In the embodiment shown in FIG. 1b, a thin SiO₂ curb layer 116 approximately 1 mm wide was deposited along the edges of the substrate layer 113 to prevent BDD growth. A copper shadow mask shielded the central sample region 115 from SiO2 deposition. After growth of BDD layer 111, the curb layer 116 was removed using HF acid etching. Contact layers 120 made of nickel 100 nm thick were deposited on the side of substrate layer 113 using a Quorum Q150T sputter coater.

The HSBD 110 shows a very strong Schottky behavior with a rectification ratio of 6×10\hat{ }8 at a bias voltage of ±1.4 V. When exposed to a ²⁴¹Am alpha particle source, the HSBD 110 of the detector 100 without any bias produced a robust peak corresponding to the 5486 keV alpha particles in the pulse height spectrum with a full-width-at-half-maximum (FWHM) of 210 keV and a charge collection efficiency of 40%. The HSBD 110 also exhibited superior responsiveness to UV radiation compared to traditional metal/4H-SiC Schottky diodes. A photo-to-dark-current ratio (PDCR) of 1.12×10⁵ and a responsivity of 0.01 A/W at 0 V was observed with the HSBD 110 exposed to 365 nm UV radiation having a power density of 3 mW/cm².

The current-voltage characteristics were measured using a Keithley 237 source-measure unit (SMU). The UV photocurrent was measured using the SMU when the devices were illuminated using a Marktech Optoelectronics MT3650N3-UV ultraviolet LED emitting at 365 nm with a spectral line half-width of 15 nm.

The alpha radiation response of the devices was assessed by illuminating the BDD window side with a ˜1.0 μCi ²⁴¹Am radioisotope emitting 5486 keV alpha particles. Measurements were conducted using a standard benchtop alpha spectrometer, including a CR110 preamplifier, an Ortec 576 spectroscopy amplifier, and a Canberra Multiport II Multi-Channel Analyzer (MCA), controlled by Genie 2000 data acquisition software. The devices were maintained under vacuum in an EMI shielded test-box during the radiation response tests.

The HSBDs 110 demonstrated an extraordinary response to radiation, achieving a responsivity at zero applied bias (self-biased) higher by an order of magnitude reported in metal/4H-SiC SBDs. Furthermore, the highly conductive BDD layer 111 serves as a contact to facilitate the extraction of radiation-induced electron-hole charge pairs generated within the 150 micron thick 4H-SiC epitaxial layers, which serve as the active detector volume. This offers potential for applications in space radiation detection and nuclear reactor core dose monitoring, surpassing the capabilities of current detector technologies. Additionally, this invention has significant implications for the manipulation of the charge state of optically active defects in 4H-SiC, laying the foundation for future developments in quantum computation qubits. Since both diamond and 4H-SiC are compatible with harsh environments, the structure also addresses challenges in harsh environment radiation detection.

By incorporating a thin, ultraviolet (UV) transparent layer of nanocrystalline boron-doped diamond (BDD) to high-quality 4H-SiC epitaxial layers, the present invention achieves an improved UV detection performance in self-biased BDD/4H-SiC heterojunction Schottky barrier devices (HSBD). This not only improves UV detection sensitivity but also opens up new possibilities for electrically controlling the UV addressable charge state of defects in 4H-SiC, which is crucial for future quantum computing applications. This invention also addresses outstanding challenges in harsh environment applications such as space/planetary radiation detection and monitoring radiation levels in nuclear core reactors.

The invention presents a novel metal-free (p⁺)BDD/(n)4H-SiC heterojunction Schottky barrier device (HSBD), achieved by depositing a nanocrystalline boron-doped diamond (BDD) layer on an n-type 4H-SiC epitaxial layer. Diamond is an ultrawide bandgap semiconductor compatible with harsh environments. While the diamond/4H-SiC heterojunction has been previously introduced, its nuclear radiation detection capabilities remain unexplored. The junction properties and UV radiation response of the devices were characterized to evaluate their suitability for UV-transparent, electrically controlled quantum metrology of defects in 4H-SiC. Additionally, the self-biased (0 V applied bias) charge collection efficiency of the HSBDs exposed to alpha particle radiation was assessed, which is crucial for radiation detection in space and planetary missions.

FIG. 1c shows the room-temperature current density-voltage (J-V) characteristics recorded without illumination (“under dark”). The device exhibited robust Schottky behavior with an excellent rectification ratio of 6.09×10⁸ at a bias voltage (±1.4 V) where the forward current reaches 1 mA. A thermionic emission model fit to the semilogarithmic J-V characteristics revealed a diode ideality factor of 1.1 and a barrier height of 1.25 eV. A diode ideality factor close to unity suggests high spatial uniformity of the surface barrier height across the 6 mm×6 mm contact area. The obtained barrier height matches that of high-resolution metal/4H-SiC Schottky barrier radiation detectors.

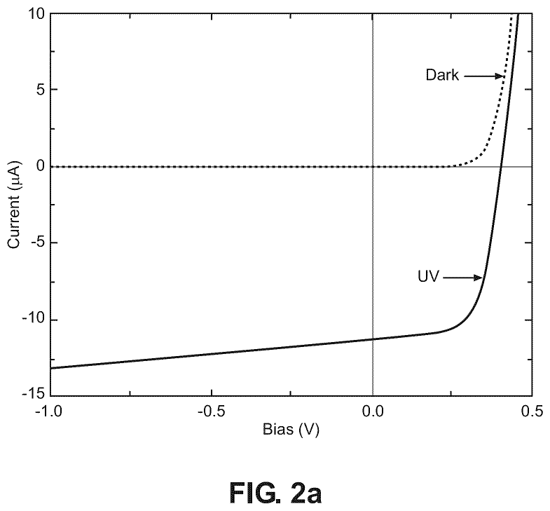

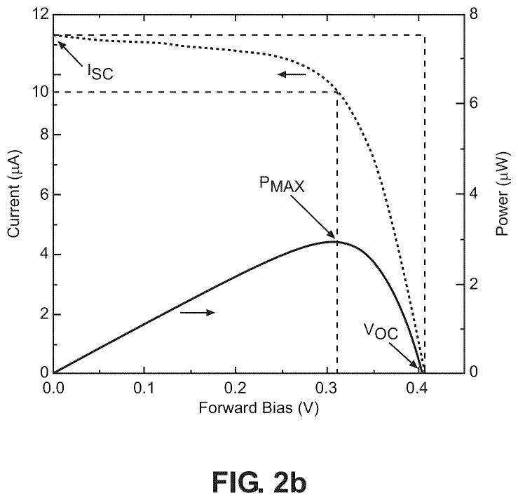

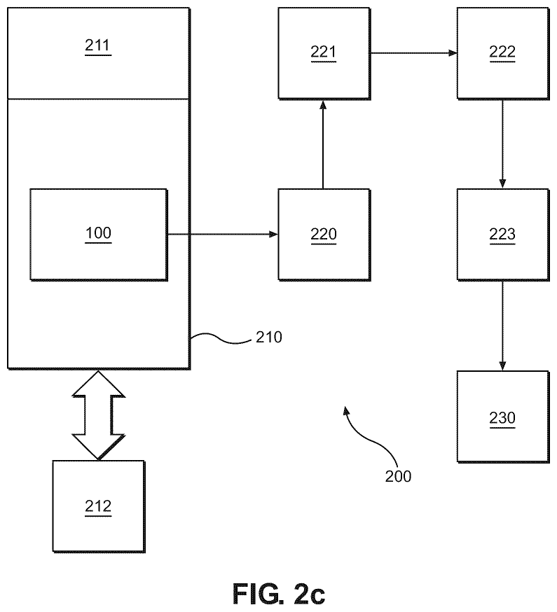

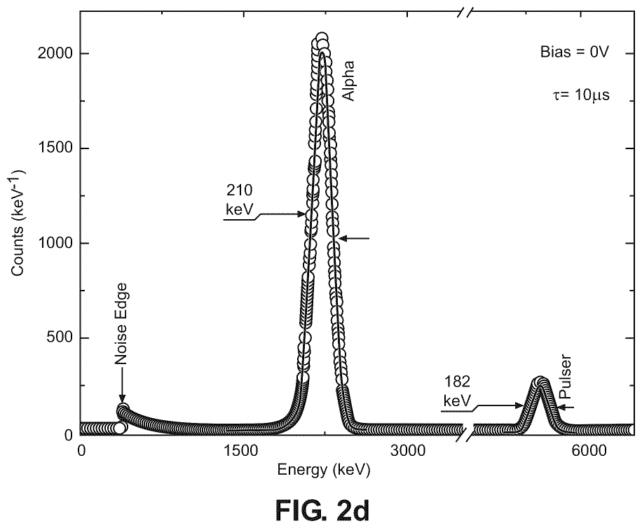

FIG. 2a presents the current-voltage (I-V) characteristics of the HSBD under 365 nm UV radiation. The photo-to-dark-current ratio (PDCR) was 1.12×10⁵ at 0 V with an incident power (Pᵢₙ) of 3 mW/cm². The responsivity (R) at 365 nm was calculated as 0.01 A/W using R=(Jₚₕ−J_{dark})/P_in, where Jₚₕ and J_{dark} are the photo-and dark-current densities, respectively. Among the best reported UV photoresponses in Ni/4H-SiC Schottky diodes, a room temperature responsivity of 0.0047 A/W measured at 365 nm has been reported. More recently, a responsivity of 0.02 A/W has been measured at 365 nm in tungsten/4H-SiC Schottky UV photodiodes fabricated using an oxygen plasma pre-treatment technology. The PDCR in their device was reported to be on the order of 10³, measured at an applied bias of 25 V and under 275 nm UV illumination. A room-temperature responsivity of 0.1 A/W at 365 nm has been reported in graphene/Si photodetectors however such detectors are not necessarily harsh environment compatible.

While photoinduced power generation is not directly related to radiation detection or spin interaction, the strong UV response suggested evaluation of the photovoltaic parameters of the device. FIG. 2b illustrates the variation of the forward current and output power with forward bias under 365 nm UV illumination. The open-circuit voltage (V_{OC}) was 0.4 V, higher than the 0.3 V reported for graphene/silicon photodetectors, indicating that the device can generate a greater potential difference in photovoltaic mode. A short-circuit current (I_{SC}) of 11.23 μA was observed, with a maximum power (Pₘₐₓ) of 3 μW and a fill-factor (FF) of 64% using FF=(V_{OC}×I_{SC})/Pₘₐₓ.

FIG. 2c depicts a schematic of the alpha spectrometer system 200 used to characterize the nuclear radiation response of the radiation detection device 100. The alpha spectrometer system 200 comprises a test box 210 containing the radiation detection device 100 and a radiation source 211 for illuminating the radiation detection device 100. In the embodiment shown, the radiation source 211 is a ²⁴¹Am alpha particle source. A vacuum pump 212 is operably connected to the test box 210 to draw a vacuum on the test box 210. The resultant signal from the radiation detection device 100 is received and processed by at least one preamplifier 220, at least one calibration pulser 221, at least one spectroscopy amplifier 222, and at least one multi-channel power amplifier 223. The processed signal is transmitted to a data acquisition system 230 for recordation and further processing.

FIG. 2d shows a pulse height spectrum obtained in the self-biased mode with the detector exposed to 5486 keV (Eᵢₙ) alpha particles. A well-resolved peak was observed with a full width at half maximum (FWHM) of 210 keV, corresponding to the 5486 keV alpha particles, and an energy peak at 2220 keV (Eₒᵤₜ). A charge collection efficiency (η=Eᵢₙ/Eₒᵤₜ) greater than 40% was calculated in the self-biased mode at 5486 keV.

An exceptional UV (365 nm) response was observed in self-biased (p⁺)BDD/(n)4H-SiC HSBDs, showing one-order of magnitude improvement in responsivity compared to metal/4H-SiC Schottky barrier diodes. Even higher responsivity is achievable at lower wavelengths. The Schottky-type rectification properties of the junction suggest potential for the electrical manipulation of qubit defect spin states. Additionally, the charged particle radiation response, demonstrated for the first time in these devices, indicates potential for high-resolution spectroscopic measurements in challenging environments.

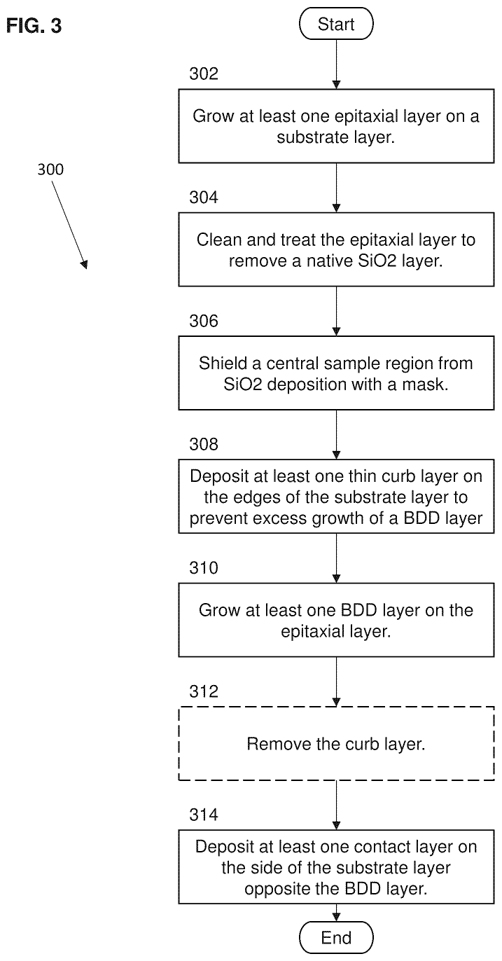

FIG. 3 illustrates a method 300 of production of the radiation detection device 100.

At block 302, at least one epitaxial layer 112 is grown on a substrate layer 113. In one embodiment, epitaxial layers 112 are grown using HWCVD. In one embodiment, epitaxial layer 112 is grown on a highly conducting n-type 4H-SiC substrate layer 113, 4° off-cut towards the (112°) direction.

At block 304, the epitaxial layer 112 is cleaned and treated to remove the native SiO₂ layer. In one embodiment, the epitaxial layer 112 is cleaned with an RCA clean protocol. In one embodiment, epitaxial layer 112 is treated with 50% diluted HF.

At block 306, a mask shields the central sample region 115 from SiO₂ deposition. In one embodiment, a shadow mask shields the central sample region 115.

In one embodiment, copper mask shields the central sample region 115. In one embodiment, a 6 mm×6 mm mask shields the central sample region 115.

At block 308, at least one thin curb layer 116 is deposited on the edges of the substrate layer 113 to prevent excess growth of the BDD layer 111. In one embodiment, the curb layer 116 is SiO₂. In one embodiment, the curb layer 116 is 1 mm wide.

At block 310, at least one BDD layer 111 is grown on the epitaxial layer 112. In one embodiment, the BDD layer 111 is grown using vapor deposition. In one embodiment, the BDD layer 111 is grown using PECVD. In one embodiment, the BDD layer 111 is grown on a 150 μm thick epitaxial layer 112. In one embodiment, the BDD layer 111 is grown on an n-type 4H-SiC epitaxial layer 112.

At optional block 312, the at least one curb layer 116 is removed. In one embodiment, the curb layer 116 is removed using acid etching. In one embodiment, the acid is HF acid.

At block 314, at least one contact layer 120 is deposited on the side of the substrate layer 113 opposite the BDD layer 111. In one embodiment, the contact layer 120 is nickel. In one embodiment, the contact layer 120 is 100 nm thick. In one embodiment, the contact layer 120 is deposited using sputter coating.

It is to be understood that this written description uses examples to disclose the invention, including the best mode, and also to enable any person skilled in the art to make anew the invention. The various embodiments of the invention may be combined in any arrangement capable of producing the invention. Any dimensions or other size descriptions are provided for purposes of illustration and are not intended to limit the scope of the claimed invention. Additional embodiments can include variations component composition, synthesis, and combination, as well as variations required for use in the industry. The patentable scope of the invention may include other examples that occur to those skilled in the art.

1. A radiation detection device, comprising:
at least one heterojunction Schottky barrier diode (HSBD), wherein the at least one HSBD comprises:
at least one boron-doped diamond (BDD) layer located on top of at least one epitaxial layer,
the at least one epitaxial layer located on top of at least one buffer layer,
the at least one buffer layer located on top of a bulk substrate layer; and
at least one contact layer located on a side of the bulk substrate layer opposite the at least one epitaxial layer.

2. The device of claim 1, wherein the at least one BDD layer comprises nanocrystalline p⁺ boron-doped diamond.

3. The device of claim 1, wherein the at least one epitaxial layer comprises n-type silicon carbide (SiC).

4. The device of claim 1, wherein the at least one epitaxial layer comprises a polytype of SiC selected from 6H-, 4H-, or 3C-polytypes of SiC.

5. The device of claim 1, wherein the at least one buffer layer comprises a polytype of SiC selected from 6H-, 4H-, or 3C-polytypes of SiC.

6. The device of claim 1, wherein the bulk substrate layer comprises n-type silicon carbide (SiC).

7. The device of claim 6, wherein the bulk substrate layer comprises SiC with a 4° off-cut towards the (112°) direction.

8. The device of claim 1, wherein the bulk substrate layer comprises a polytype of SiC selected from 6H-, 4H-, or 3C-polytypes of SiC.

9. The device of claim 1, wherein the at least one contact layer is located on a central sample region.

10. The device of claim 1, wherein the at least one contact layer is a metal selected from the group consisting of: nickel, molybdenum, and palladium.

11. The device of claim 1, further comprising at least one curb layer on an edge of the HSBD surrounding a central sample region.

12. The device of claim 11, wherein the curb layer is selected from the group consisting of: silicon dioxide, silicon nitride, zinc oxide, and aluminum nitride.

13. A method of manufacturing a radiation detection device, comprising:
growing at least one epitaxial layer on a substrate layer;
cleaning and treating the epitaxial layer to remove a native SiO₂ layer;
shielding a central sample region from SiO₂ deposition;
depositing at least one thin curb layer on the edges of the substrate layer to prevent excess growth of at least one BDD layer;
growing the at least one BDD layer on at least one epitaxial layer; and
depositing at least one contact layer on a side of the substrate layer opposite the at least one BDD layer.

14. The method of claim 13, further comprising removing the at least one curb layer.

15. The method of claim 14, wherein the at least one curb layer is removed using acid etching.

16. The method of claim 13, wherein the at least one epitaxial layer is grown using HWCVD.

17. The method of claim 13, wherein the at least one epitaxial layer is cleaned with an RCA clean protocol.

18. The method of claim 13, wherein the at least one BDD layer is grown using PECVD.

19. The method of claim 13, wherein the at least one contact layer is deposited using physical vapor deposition.

20. The method of claim 19, wherein the at least one contact layer is deposited using sputter coating.
